(19) United States
(12) Patent Application Publication
(10) Pub. No.: US 2010/0167427 A1
(43) Pub. Date: Jul. 1, 2010

(54) PASSIVE DEVICE TRIMMING

(75) Inventors: Gregory E. Howard, Plano, TX (US); Leland Swanson, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/402,673

(22) Filed: Mar. 12, 2009

Related U.S. Application Data
(60) Provisional application No. 61/141,759, filed on Dec. 31, 2008.

(51) Int. Cl. H01L 21/66

(52) U.S. Cl. 438/13; 438/5; 257/E21.53; 257/E21.531

(57) ABSTRACT

The present invention relates to a method for trimming passive devices during fabrication to account for process variations. More particularly, the present invention relates to a method by which an adjustable device layer comprised within a passive device (e.g., resistor body, capacitor electrodes) can be measured and subsequently trimmed (e.g., etched to reduce size) during processing to correct for process variations. Essentially, an operational parameter is measured for a plurality of passive devices. The measurements are used to form an adjustment map for a region of a semiconductor body (e.g., wafer) comprising information pertaining to operational parameters as a function of spatial coordinates. The adjustment map is utilized by a DMD projector configured to pattern openings into a hardmask configured over the adjustable device layer. The adjustable device layer is then etched in regions not protected by the hardmask, thereby effectively trimming the passive device according to the adjustment map.

### RELATED APPLICATION

This application claims priority to Ser. No. 61/141,759 filed Dec. 31, 2008, which is entitled “Passive Device Trimming”.

### FIELD

The disclosure herein relates generally to semiconductor processing, and more particularly, to a method of reducing the effect of process variation in the fabrication of passive devices.

### BACKGROUND

Integrated chips are formed by complex fabrication processes comprising a plurality of steps including film depositions, dopings, thermal anneals, etc. These complex processes can be used to form integrated chips having a plurality of diverse devices (e.g., analog devices, digital devices, etc.). For example, single integrated chips having broad functionality (e.g., digital, analog, mixed-signal, and radio-frequency functions) that may extend into the radio frequency and mixed-signal areas require the integration of passive devices, such as capacitors and/or resistors, on to an IC die. Many devices have operational characteristics that are heavily dependent upon their spatial layout. Therefore, during the formation of such devices variations in the fabrication process (process variations) can impact on the operational characteristics of such devices by changing the spatial layout of the devices.

For example, there are various types of capacitors that can be used on integrated chips. Metal-oxide-silicon (MOS) capacitors can be used as a passive capacitor. Metal-insulator-metal capacitors (MIM or MIM cap) are also commonly found in integrated chips. As the name implies, MIM caps are usually found between interconnect metal levels. MIM caps are integrated into various integrated circuits for applications such as analog-logic, analog-to-digital, mixed signal and radio frequency circuits. Current methods of integrating MIM caps into integrated circuits require multiple photolithographic and etching steps.

FIG. 1 illustrates a cross sectional view of a typical MIM capacitor, and although FIG. 1 illustrates a MIM cap, it will be appreciated that other capacitors (e.g., MOS caps) share a similar structure. As shown in FIG. 1, a MIM cap 100 is formed over a semiconductor body 102. The MIM cap 100 is configured to comprise a lower gate electrode layer 104 (e.g., M3) comprised within dielectric material 106 and an upper gate electrode layer 110 (e.g., M4) comprised within dielectric material 112. As shown in FIG. 1, the lower gate electrode 104 is vertically separated from the upper gate electrode layer 110 by one or more dielectric layers 108. Typically the one or more dielectric layers 108 are comprised of high k dielectric material to increase capacitance of the device 100 while decreasing the size. Precision capacitors often use one or more dielectric layers comprising an oxide-nitride-oxide (ONO) dielectric stack, which allows for thinner layers and increased performance. Alternatively, other materials such as tantalum oxide (Ta₂O₅) or hafnium oxide (HfO₂) may also be used. It will be appreciated that capacitors may also comprise additional layers between the lower and upper metal plates also.

Similarly, semiconductor resistors may be formed in a variety of manners (e.g., diffused resistors; ion-implanted resistors; thin-film resistors; and polysilicon resistors) on an integrated chip. FIGS. 2A-2C illustrate exemplary structures of typical semiconductor resistors. As shown in FIG. 2A, a resistor is essentially an electrically resistive path comprised between metal interconnect wires 212. A resistor is formed on an insulating layer 202 and comprises a resistor body 204 and resistor heads 206. As shown in FIG. 2B, resistors can be formed to have a body 204 and heads 206 comprised of doped polysilicon. Alternatively, as shown in FIG. 2C, resistors can be formed to have a body 204 of polysilicon and heads 206 of a low resistance silicide (e.g., Titanium silicide), wherein the heads 206 of low resistance silicide are configured above the underlying polysilicon resistor body 204. In either structure, contacts 208 are configured to coupled the resistor heads 206 to a metal interconnect 212.

During fabrication, a polysilicon layer is typically deposited onto an insulating layer 202 formed above a semiconductor body 102 (e.g., wafer). The polysilicon layer is then implanted with the right type and amount of impurity. For example, boron or phosphorus can be provided to the polysilicon to render it conductive. The quantity of such impurities provided within the polysilicon layer will vary its conductivity. The polysilicon is then patterned using photoresist and is subsequently etched (e.g., RIE etch) to define the shape of the resistor (e.g., comprising resistor body 204 and resistor heads 206). The resistor values are controlled by the cross-sectional area (e.g., height and width), the length, and the resistivity (e.g., impurity concentration), of the polysilicon. Accordingly, various resistors can be formed of polysilicon of a selected resistance depending upon impurity concentration.

### SUMMARY

The following presents a simplified summary in order to provide a basic understanding of one or more aspects of the invention. This summary presents one or more concepts of the invention in a simplified form as a prelude to the more detailed description that is presented later and is not an extensive overview of the invention. In this regard, the summary is not intended to identify key or critical elements of the invention, nor does the summary delineate the scope of the invention.

The present invention relates to a method for trimming passive devices during fabrication to account for process variations. More particularly, the present invention relates to a method by which an adjustable device layer comprised within a passive device (e.g., resistor body, capacitor electrodes) can be measured and subsequently trimmed during processing to correct for process variations. Essentially, an operational parameter is measured for a plurality of passive devices, wherein the measured parameters relate to an adjustable device layer. The measurements are used to form an adjustment map for a region of a semiconductor body (e.g., wafer). The adjustment map comprises information pertaining to the operational parameter of passive devices as a function of spatial coordinates on the semiconductor body. The adjustment map is basically a two dimensional contour map illustrating adjustments (e.g., as a percentage) that are to be made to the adjustable device layer to cause the operational parameter of a device to achieve a nominal designed value. In one embodiment, the adjustment map is utilized by a digital micromirror device (DMD) exposure system (i.e., DMD projector) which is configured to pattern openings into a hard mask configured over the adjustable device layer. The semiconductor body is then selectively etched in regions not protected by the hard mask (e.g., photoresist), thereby effectively trimming the passive device according to the adjustment map. The result is that the passive device is modified to account for the process variation so that the device is once again brought into line with the designed operational parameters.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 illustrates a cross sectional view of a typical semiconductor MIM capacitor;

FIGS. 2A-2C illustrate exemplary structures of a typical semiconductor resistor;

FIG. 3 illustrates a flow diagram showing a method of improved process control of passive devices;

FIG. 4 illustrates a flow diagram showing a particular embodiment of the present invention illustrating a flow diagram showing a method of improved process control of a semiconductor capacitor;

FIG. 5 illustrates an adjustment map of the section of the semiconductor wafer;

FIG. 6 illustrates a top view of a section of a semiconductor wafer comprising an array of semiconductor capacitors;

FIG. 7 illustrates an adjustment map of the section of the semiconductor wafer comprising an array of semiconductor capacitors;

FIG. 8 illustrates a top view of the semiconductor wafer comprising an array of semiconductor capacitors with an overlaid hard mask comprising openings to expose the underlying layers to an etch;

FIG. 9 illustrates a top view of the semiconductor wafer comprising an array of semiconductor capacitors after the underlying layer has undergone the etch;

FIG. 10 illustrates a flow diagram showing a particular embodiment of the present invention illustrating a flow diagram showing a method of improved process control of a semiconductor resistor;

FIG. 11 illustrates a top view of a section of a semiconductor wafer comprising an array of semiconductor resistors;

FIGS. 12 illustrates an adjustment map of the section of a semiconductor wafer comprising an array of semiconductor resistors;

FIGS. 13-14 illustrate top and side views of a method for trimming a semiconductor resistor according to the method of FIG. 10;

FIGS. 15-16 illustrate top and side views of an alternative method for trimming a semiconductor resistor according to the method of FIG. 10; and

FIGS. 17-18 illustrate top and side views of yet another alternative method for trimming a semiconductor resistor according to the method of FIG. 1 0.

### DETAILED DESCRIPTION OF THE INVENTION

The description herein is made with reference to the drawings, wherein like reference numerals are generally utilized to refer to like elements throughout, and wherein the various structures are not necessarily drawn to scale. In the following description, for purposes of explanation, numerous specific details are set forth in order to facilitate understanding. It may be evident, however, to one skilled in the art, that one or more aspects described herein may be practiced with a lesser degree of these specific details. In other instances, known structures and devices are shown in block diagram form to facilitate understanding.

Parameter variations over process (e.g., lot to lot, wafer to wafer and even within the wafer) for discrete components formed onto integrated chips can have a large impact on device performance, in some cases causing on-wafer components to vary from design by as much as 20% of the device size. In the case of analog designs, such wide variance in passive components are rarely optimal, leaving the size of a design bigger than it could be or the performance below what could be achieved. Present solutions to this problem include the performance of post processing trimming use laser cuts or electrical fuses, either pre or post packaging. Unfortunately these solutions have a number of disadvantages. For example, trimming is expensive (e.g., excessive probe costs per market requirements, excessive testing cost and performance requirements), time consuming, and not always possible due to die area limitations (e.g., due to extra trim pads, extra laserable links. Accordingly, a process with improved process control of devices (e.g., analog, digital) is provided herein.

The present invention relates to a method for trimming passive devices during fabrication to account for process variations. More particularly, the present invention relates to a method by which an adjustable device layer comprised within a passive device (e.g., resistor body, capacitor electrodes) can be measured and subsequently trimmed during processing to correct for process variations. Essentially, an operational parameter is measured for a plurality of passive devices, wherein the measured parameters relate to an adjustable device layer. The measurements are used to form an adjustment map for a region of a semiconductor body (e.g., wafer). The adjustment map comprises information pertaining to the operational parameter of passive devices as a function of spatial coordinates on the semiconductor body. The adjustment map is basically a two dimensional contour map illustrating adjustments (e.g., as a percentage) that are to be made to the adjustable device layer to cause the operational parameter of a device to achieve a nominal designed value. In one embodiment, the adjustment map is utilized by a digital micromirror device (DMD) exposure system (i.e., DMD projector) which is configured to pattern openings into a hard mask (e.g., photoresist) configured over the adjustable device layer. The semiconductor body is then selectively etched in regions not protected by the hard mask, thereby effectively trimming the passive device according to the adjustment map. The result is that the passive device is modified to account for the process variation so that the device is once again brought into line with the designed operational parameters.

FIG. 3 illustrates a first embodiment of the present invention, a method 300 for improved process control of passive devices. While method 300 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the disclosure herein. Also, one or more of the acts depicted herein may be carried out in one or more separate acts and/or phases.

At 302 an adjustable device layer of a passive device is formed over a semiconductor body (e.g., wafer). The adjustable device layer is comprised within the passive device, and in this process can be subsequently adjusted to adjust the passive device's operational parameters. For example, the adjustable device layer comprises a layer that affects the characteristics of the device through its geometric qualities (e.g., height, width, length, etc.). In one embodiment, the adjustable device layer may comprise a capacitor dielectric layer of a capacitor, since the thickness of the dielectric layer is directly related to the device parameter of capacitance. In another embodiment, the adjustable device layer may comprise the polysilicon layer (e.g., resistor body) of a thin film resistor, since the length and width of a polysilicon layer are directly related to the device parameter of resistance.

Operation parameters of a plurality of passive devices are measure based upon the adjustable device layer at 304. As stated above, the operational parameters are related to an adjustable device layer of the devices, thereby allowing the adjustable device layer to be subsequently adjusted according to method 100. In one embodiment, operational parameters associated with the adjustable device layer may be measured at one or more locations on respective passive devices (e.g., resistors, capacitors) of an array.

At 306 an adjustment map is formed. The adjustment map is formed from the measurements taken at 304. The adjustment map illustrates the measured operational parameters of the plurality of passive devices as a function of their spatial position on the semiconductor body (e.g., wafer). The measurements are fitted to the adjustment map over the spatial coordinates of the semiconductor body. In one embodiment, the measured operational parameters are compared to the desired operational parameters at a given die location. The difference between the measured and the desired operational parameters is formed into a detail percentage adjustment to the operational parameters required to achieve a designed value within respective contours.

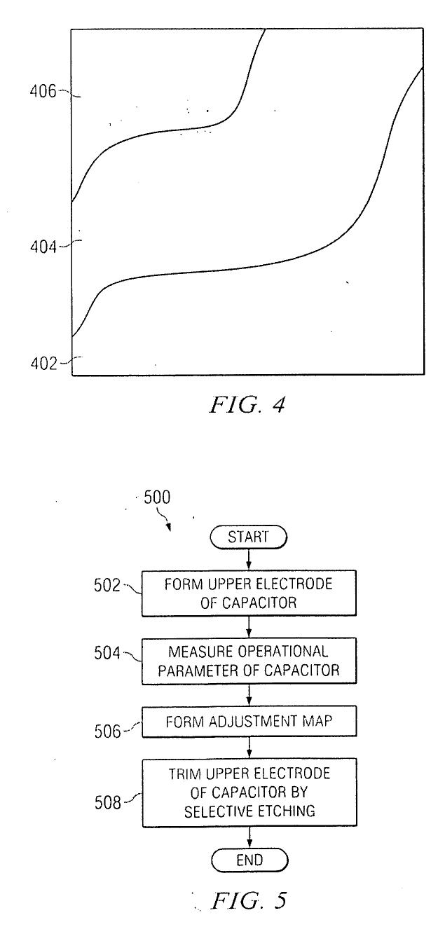

For example, as shown in FIG. 4, the adjustment map illustrates a region 402 having a nominal operational parameter which would require no adjustment, a region 404 which would require a 10% adjustment to the operational parameters of devices comprised within the contour to achieve the nominal design value, and a region 406 which has would require a 20% adjustment to the operational parameters of devices comprised within the contour to achieve the nominal design value. In other words, if the operational parameters of the passive devices were adjusted according to the percentages denoted in the adjustment map the passive devices would have uniform operational parameters over the surface of the given region of the semiconductor body.

The adjustable device layer comprised within a plurality of passive devices is trimmed, based upon the adjustment map, to respective design value at 308. In one particular embodiment, adjustment is performed by utilizing the adjustment map to form an etch mask layer (e.g., photomask) which is patterned by a reticleless exposure system. In one embodiment, the exposure of the etch mask layer is controlled by a spatial light modulator (SLM) exposure system (i.e., an optical maskless lithography system). The maskless lithography system replaces a reticle with a spatial light modulator (SLM), notably a digital micromirror device (DMD), a liquid crystal display (LCD), or the like. The SLM includes an array of active areas (e.g., mirrors or transmissive areas) that can be modulated to form a desired pattern. An algorithm, based on the adjustment map, defines a desired exposure pattern which is used to modulate the active areas. Preferably, the SLM is arranged to enable suitable exposure of all desired areas on a substrate for each pattern during only one pass of the substrate.

In one particular embodiment, the adjustment map is utilized in a low resolution (micron level) digital micro-mirror (DMD) exposure system to selectively expose the photomask by using the switching of a micromechanical mirror on the fly mask. In such an embodiment, the DMD exposure system forms a photo mask (i.e., a photoresist mask) which provides an on the fly lithography approach that allows very fast adjustments (e.g., typically less than a minute across a wafer) to be made to the adjustable film thickness during the fabrication process

Trimming of the adjustable device layer is completed by selectively etching the semiconductor body based upon the patterned etch mask layer. It will be appreciated that trimming refers to selectively etching the selectively patterned etch mask layer to trim the underlying adjustable film in regions exposed by the etch mask layer. Selective etching adjusts the geometric qualities (e.g., length, width) of the adjustable device layer thereby adjusting the operational parameters of the passive devices. In one embodiment, a wet etchant can be used for selective etching of the adjustable device layer. In another embodiment, a plasma etchant can be used for selective etching of the adjustable device layer.

Therefore, as provided above, the method 300 provides an in-situ adjustment of an adjustable device layer thereby providing an improvement in process control which results in improved device performance for integrated chips.

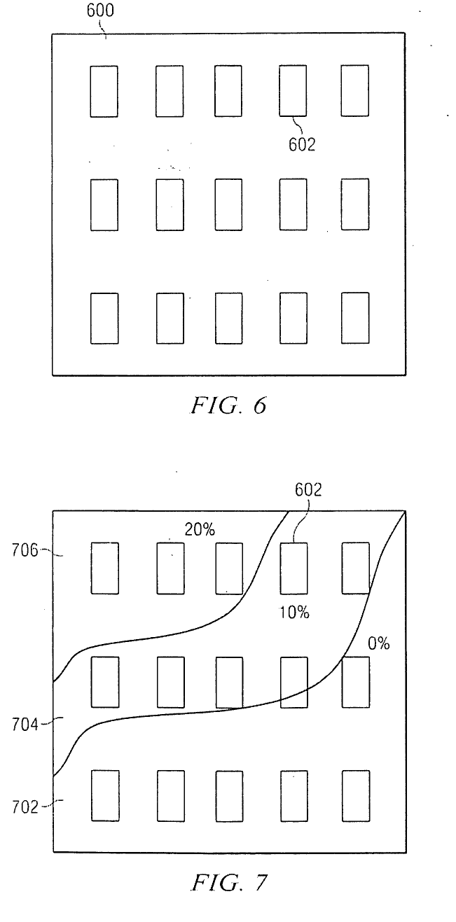

FIG. 5 illustrates a particular embodiment of the present invention, a method 500 wherein in-situ adjustment of a capacitor's upper plate layer is performed. FIGS. 6-9 are included to aid in the understanding of method 500.

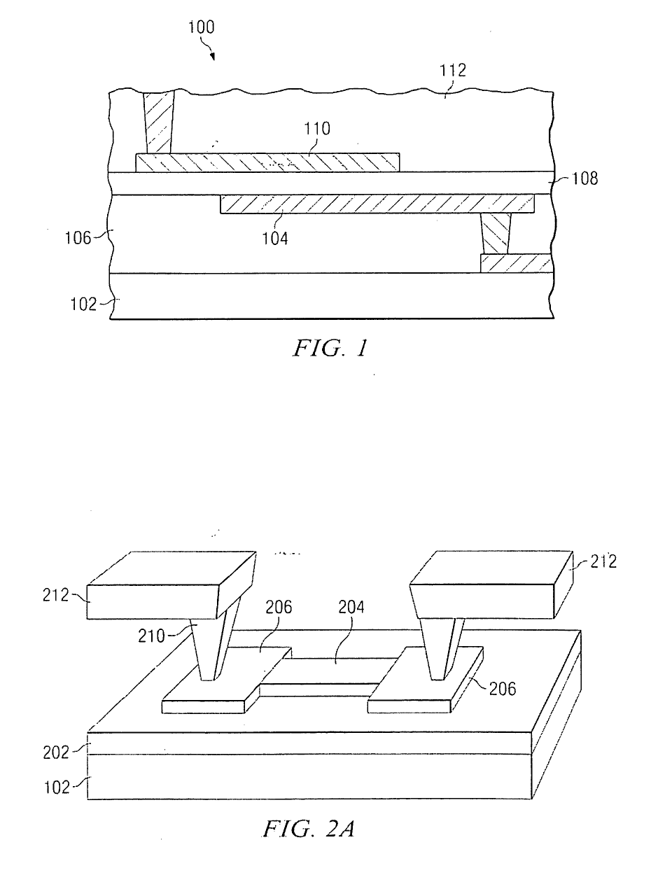

At 502 an upper electrode of a capacitor is formed. In one embodiment, the upper electrode the capacitor is formed by depositing a metal layer above one or more dielectric layers (e.g., high-k dielectric layers). The metal layer is formed to a predetermined thickness (e.g., 300 nm) and then selectively patterned using lithography techniques which are well known in the art. In one embodiment, the upper layer comprises a back end of the line interconnect metal (e.g., copper metal interconnect layer) and completes the formation of a back end of the line capacitor (e.g., as shown FIG. 1). FIG. 6 illustrates a top view of a region of a semiconductor body 600 (e.g., wafer) comprising an array of semiconductor capacitors, wherein the upper electrode 602 of respective capacitors is visible.

An operational parameter of respective capacitors within the capacitor array is measured at 504. Due to process variation in the different levels of the capacitor (e.g., variations in the thickness of the capacitor dielectric) the capacitance of devices within the array will vary between capacitors. In one embodiment, the operational parameter comprises the capacitive density. In an alternative embodiment, the operational parameter comprises a capacitor dielectric thickness.

At 506 an adjustment map is formed. The adjustment map is formed from measurements of the operation parameters taken at 502. In one embodiment, the adjustment map comprises a detail percentage adjustment to the operational parameters required to achieve nominal operational parameters within respective contours. For example, as shown in FIG. 7 the adjustment map illustrates a region 702 having a nominal (i.e., designed) operational parameter which would require no adjustment, a region 704 which would require a 10% adjustment to achieve the nominal (i.e., designed) operational parameter of the capacitor, and a region 706 which would require a 20% percent adjustment to achieve the nominal (i.e., designed) operational parameter of the capacitor. In other words, if the adjustable film were adjusted according to the percentages of the adjustment map the operational parameters of the capacitors would be uniform over the surface of the given region of the semiconductor body.

By mapping the changes in operational parameters of the capacitors a size adjustment to the upper electrode of the capacitor can be determined to account for the variation. This allows for removing process variations and brings capacitors back into line with their designed values (i.e., re-centers the process). For example, as shown in FIG. 7, the adjustment map allows for determination of what adjustments to the size of the capacitor's upper electrode must be made. If the capacitors upper electrode is reduced in size the capacitive value of a respective capacitor is reduced (i.e., since C=κ·ε₀A/d, wherein C is the capacitance, d is the distance between electrodes, A is the area of the electrodes, and κ,ε₀ are constants).

The upper electrode of the capacitors is trimmed by selectively etching the upper electrode at 508. More particularly, trimming is performed by selectively patterning an etch mask layer configured above the upper electrode layer and the etching the semiconductor body. In one embodiment, trimming may be performed through use of a low resolution (micron level) digital micro-mirror mask (DMD exposure) to selectively expose a hard mask photoresist layer configured above the upper electrode layer of a capacitor. The photoresist layer is then utilized as an etch mask to selectively etch the upper electrode layer to an appropriate size determined by the adjustment map. The information from the adjustment map can be feed into the DMD exposure tool and by varying the active areas (e.g., mirrors or transmissive areas) the desired pattern can be formed. In an alternative embodiment, the adjustment may be performed by patterning a hard mask photoresist layer using traditional lithography methods, however such methods would be disadvantageous compared to the DMD exposure system approach since the time and expense required to form the reticle mask would be extremely high.

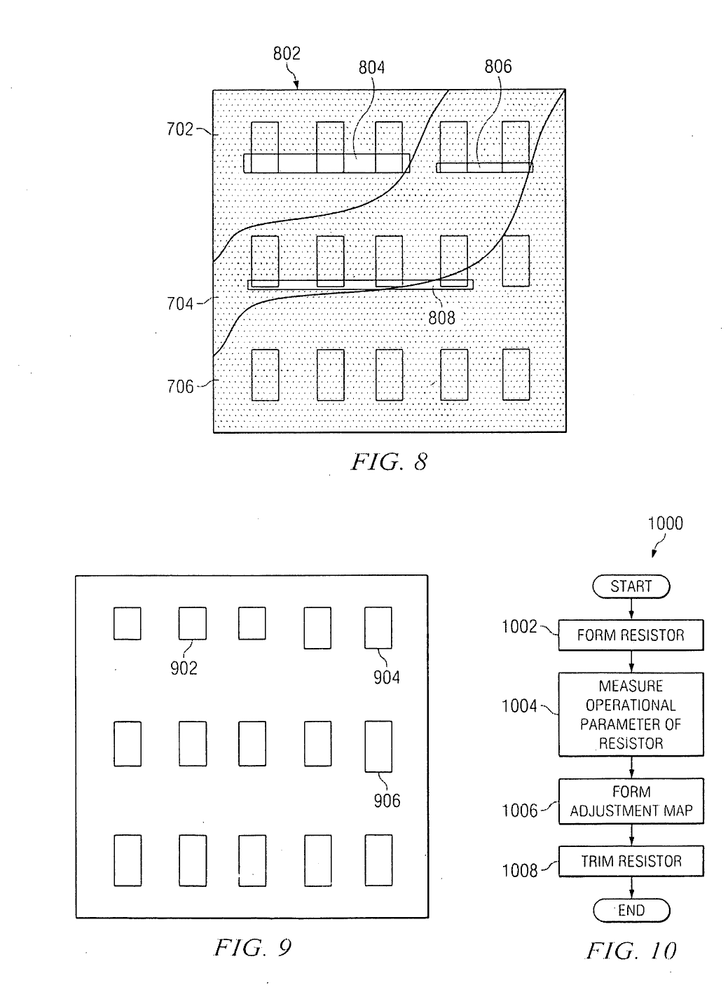

FIG. 8 illustrates a particular embodiment, wherein a photoresist mask layer 802 is deposited onto the substrate of the semiconductor body (e.g., wafer) to form a hard mask. In such an embodiment, the photoresist mask layer 802 is selectively patterned by a DMD exposure system resulting in formation of one or more openings in the hard mask (804, 806, 808) which expose areas of the adjustable device layer. The openings are dependent upon the values of the adjustment map. For example, as shown in FIG. 8, the upper capacitor electrodes, comprised within region 702 (e.g., having the highest capacitance), will undergo the largest reduction in size due to etching (e.g., reduction of the area of the upper plate will reduce the capacitance of capacitors thereby adjusting the capacitance to appropriate values). Accordingly, the DMD patterning forms opening 804 in the photoresist mask layer of region 702. The upper capacitor electrodes comprised within region 704 (e.g., having a 10% above nominal capacitance), will undergo a smaller reduction in size due to etching and accordingly the DMD patterning forms opening 806 and 808 in the photoresist mask layer of region 704. The upper capacitor electrodes comprised within region 706 (e.g., having nominal capacitance) will not undergo etching and accordingly the DMD patterning does not form an opening above the upper capacitor electrodes in region 706.

The exposed areas are then selectively etched to remove the adjustable device layer from the exposed area. The etch may comprise a wet etch or a plasma etch, for example. In alternative embodiments, alternative hard masks may be deposited onto the wafer and selectively etched using the DMD exposure technique (e.g., via a photoresist layer). Once the adjustment is made the mask is removed (e.g., by etching) resulting in an array of capacitors having operational parameters (e.g., capacitance values) matching the designed values.

FIG. 9 illustrates the upper electrodes of the capacitor array after selective etching of the exposed areas. The resulting upper electrodes vary in size according to the adjustment map. The upper electrodes 902 in region 702 have undergone the largest reduction in size resulting in a reduction of capacitance by 20%. The upper electrodes 904 in region 704 have been reduced in size resulting in a reduction of capacitance by 10%. The upper electrodes 906 remain the same size thereby resulting in no reduction in capacitance. Therefore, the resultant array has a consistent capacitance over the array. Accordingly, the method of FIG. 5 provides an in-situ adjustment of an upper capacitor electrodes thereby providing an improvement in process control which results in improved device performance for integrated chips.

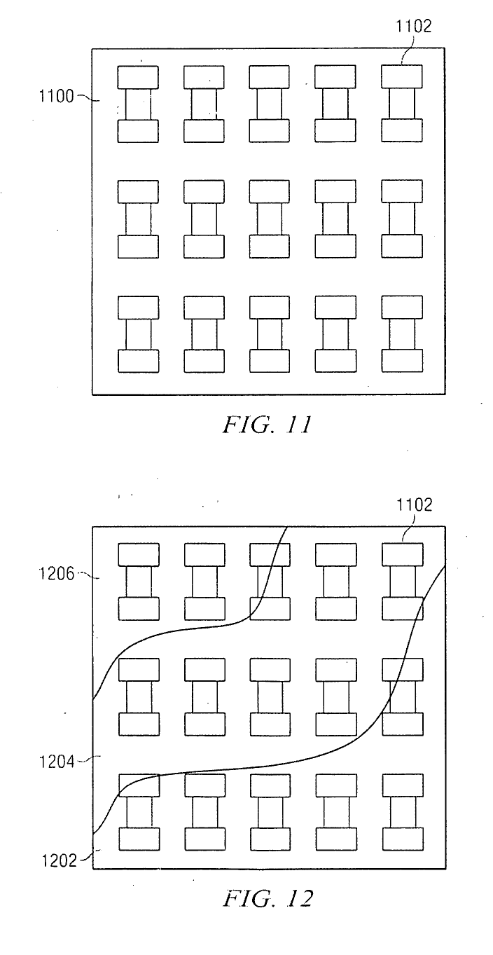

FIG. 10 illustrates a particular embodiment of the present invention, a method 1000 wherein the resistance of a resistor is measured and adjusted during fabrication of the device. FIGS. 11-18 are included to aid in the understanding of the method 1000.

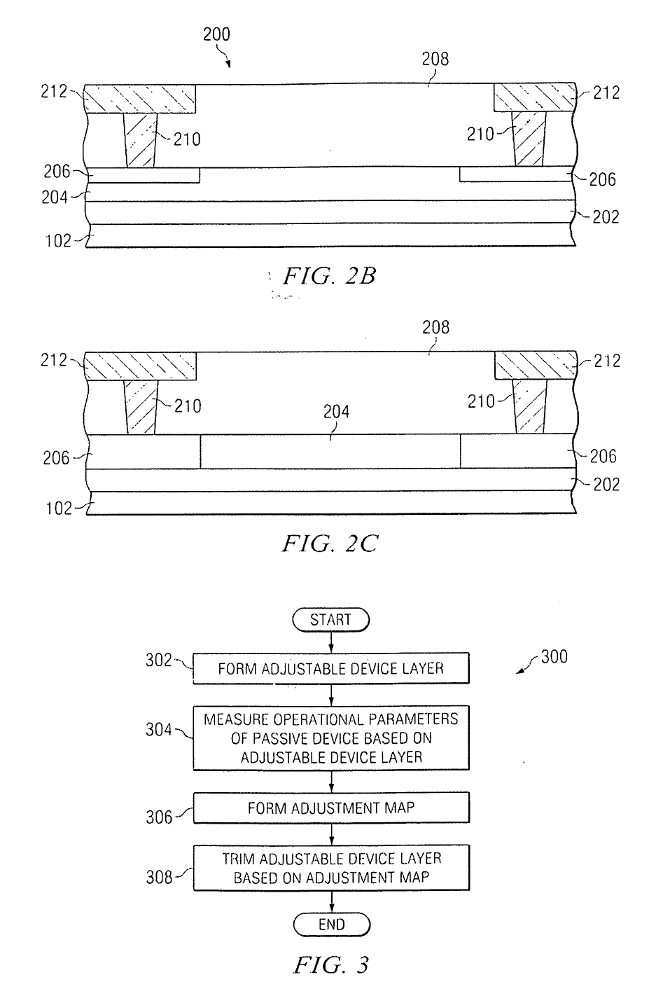

At 1002 the resistor is formed. In one embodiment, formation of the resistor comprises forming a resistor body and heads comprised of a layer of lightly doped polysilicon layer formed between two metal layers (e.g., FIG. 2B). In an alternative embodiment, formation of the resistor comprises forming a resistor body of polysilicon and heads of silicide configured between two metal layers (e.g., FIG. 2C). Polysilicon offers a high sheet resistance value in a material that is easily patterned and widely available. The resistive body is designed to have a resistance value which is a function of the resistivity of the resistor body (e.g., polysilicon) and its geometric dimensions (e.g., the length of the resistor, and the width of the resistor, and the height of the resistor). Therefore, due to process variation in the length width and doping of the resistive element, the resistance of the resistor may vary (e.g., if the polysilicon is doped more heavily than designed, the resistance of the resistor will be lower than designed).

FIG. 11 illustrates a top view of a section of a semiconductor wafer comprising an array of semiconductor resistors 1102, wherein a first resistor head, a resistor body, and a second resistor head are visible. Due to process variation in the geometric properties of the resistor body and heads (e.g., length, width, and height) the resistance of resistors comprised within the array will vary as a function of their spatial position on the semiconductor body (e.g., wafer).

At 1004 the sheet resistance of respective resistors within the array are measured. In one embodiment, where the resistive element comprises a polysilicon layer, the polysilicon sheet resistance is measured after deposition (and annealing if necessary). In one embodiment, the resistance measurement is performed by probing the polysilicon layer at a position on the resistor heads where contacts are designed (e.g., element 208 in FIG. 2A-2B), therefore providing an accurate measurement of the final resistance that would be experienced when the resistor is integrated between interconnect layers.

At 1006 an adjustment map is formed. The adjustment map is formed from the measurements of the sheet resistance taken at 1004. The adjustment map illustrates the sheet resistance of resistors as a function of their spatial position on the semiconductor body. In one embodiment, the measured (e.g., calculated) sheet resistance is compared to the desired sheet resistance at a given die location. The difference between the measured sheet resistance and the desired resistance is formed into a detail percentage adjustment to the sheet resistance required to achieve nominal designed sheet resistance within respective contours. This map details the percentage adjustment that would have to be made to resistors within respective contours to achieve the desired resistance.

FIG. 12 illustrates an example of an adjustment map having three sections of varying sheet resistivities. In particular, the adjustment map illustrates three different regions 1202, 1204, and 1206: region 1206 comprises resistors 1102 having a sheet resistance that is 20% larger than the nominal designed value, region 1204 comprises resistors 1102 having a sheet resistance that is 10% larger than the nominal designed value, and region 1202 comprises resistors 1102 having a sheet resistance that is equal to the nominal design value. In other words, if the sheet resistance of the resistors 1102 were adjusted according to the percentages of the adjustment map the sheet resistances of the resistors 1102 would be more uniform over the surface of the given region of the semiconductor body.

By mapping the changes in sheet resistance an adjustment to the resistors in respective regions can be determined to account for the variation. This allows for removing process variation and brings devices back into line with their designed values (i.e., re-centers the process). For example, as shown in FIGS. 2A-2C, if the length of a resistor body is increased it will result in a larger resistance (i.e., since R=ρ·L/A, wherein L is the length of the resistor body, A is the cross sectional area of the resistor body, and p is the resistivity). Similarly if the width of a resistor body is decreased it will result in a larger resistance.

Respective resistors comprised within the resistor array are trimmed at 1008. Trimming may be performed through use of a lower resolution (micron level) digital micro-mirror mask in a selective etch process of the resistor heads or body to the size determined by the adjustment map. Trimming in such a manner allows resistors within different regions of the chip which have outlying resistive values (e.g., regions with high or low resistive values) to be adjusted during the processing flow. In one embodiment, the resistance of a resistor is increased by increasing the length of a resistive path configured between metal interconnect layers (e.g., lengthening the resistive path between interconnects 212 shown in FIG. 2A). In an alternative embodiment, the resistance of a resistor is increased by decreasing the width of a resistive path configured between metal interconnect layers.

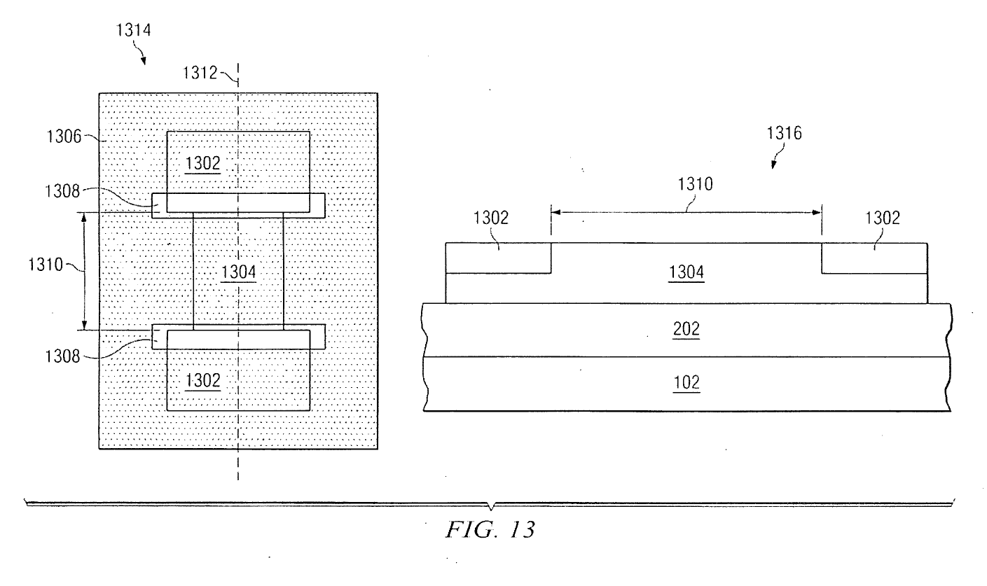

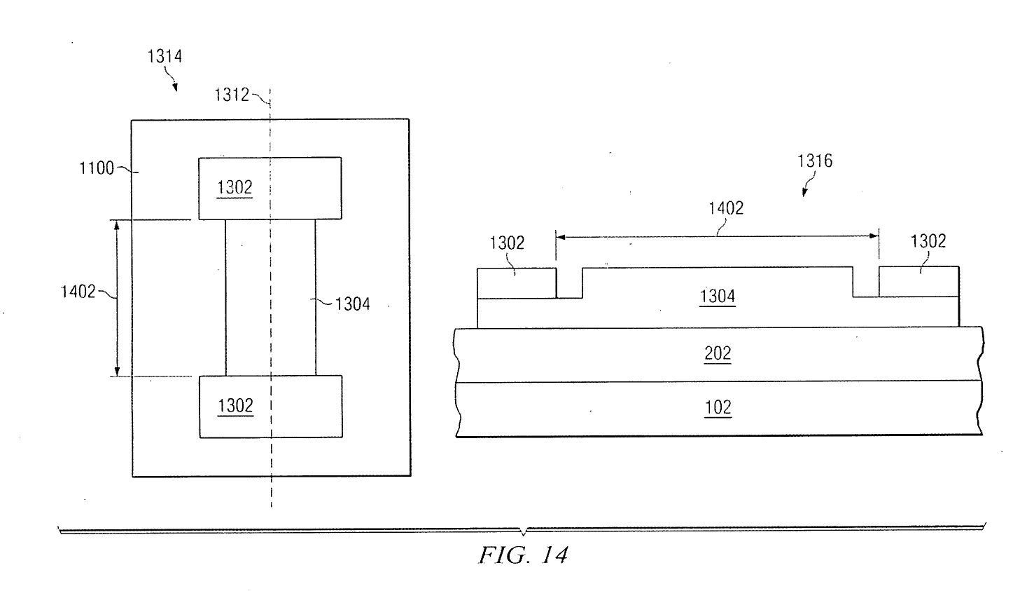

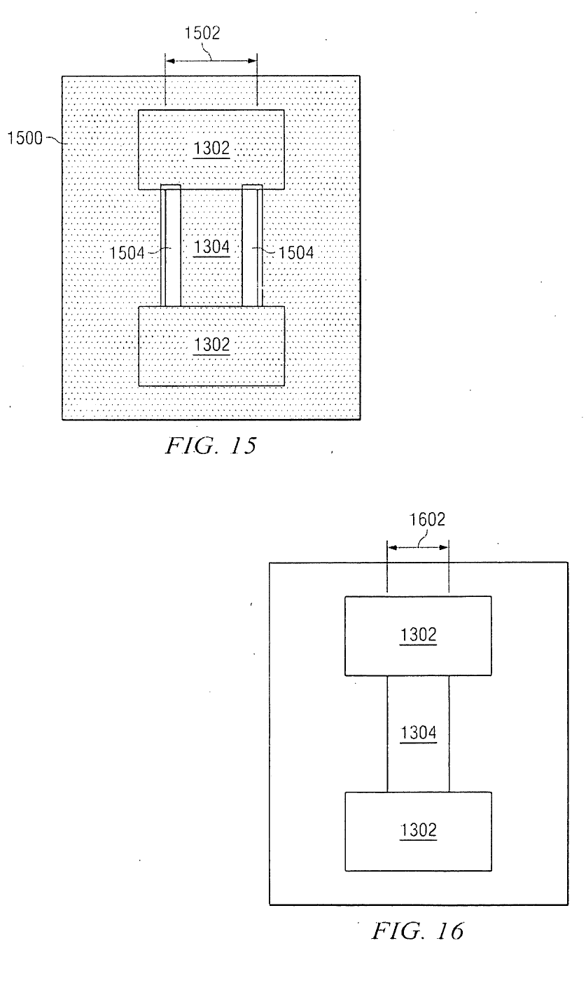

In one particular embodiment, illustrated in FIGS. 13-14, the length of a resistor body is increased. FIGS. 13-14 illustrate top and side views of a semiconductor resistor, wherein 1312 shows the cross section taken of 1314 illustrated in 1316. More particularly, FIG. 13 illustrates a resistor after formation of a polysilicon resistor body 1304, wherein the length of the resistor body 1304 is shown as width 1310. If the adjustment map shows that the resistance of the resistor is too small than an adjustment can be made to the resistor. The adjustment comprises changing the head silicide mask 1302 slightly to bring the resistance back into line with the desired value. More particular, as shown in FIG. 13, the openings 1308 are formed in an etch mask above the resistor heads 1302. The openings 1308 expose the underlying silicide layer at the edge of the resistor heads 1302. The semiconductor body is then etched such that the silicide heads 1302 exposed by the openings 1308 in the etch mask is removed, thereby reducing the width of the resistor body 1304. After the etch mask is removed, the resultant resistor is illustrated in FIG. 14, wherein the length of the resistor body 1304 has been increased from a length 1310 to a length 1402. Therefore, the length of the highly resistive resistor body is adjusted from 1310 to 1402 (i.e., wherein 1402 is greater than 1310) thereby increasing the distance that current must travel and accordingly increasing the resistor value (i.e., increasing the length of the resistor body, L, wherein R=ρ·L/A). In other words, the silicide head is adjusted to alter the resistance of the polysilicon resistor In an alternative embodiment, the width of a resistor body is decreased. FIGS. 15-16 illustrates such an embodiment. FIG. 13 illustrates a resistor after formation of a polysilicon resistor body 1304, wherein the width of the resistor body is shown as width 1502. If the adjustment map shows that the resistance of the resistor is too small than an adjustment can be made to the resistor. The adjustment comprises forming a mask 1500 above the polysilicon layer (e.g., comprising 1302 and 1304) and patterning openings 1504 into the mask 1500 along the edges of the resistor body 1304. The semiconductor body is then etched such that the polysilicon resistor body 1304 exposed by the openings 1504 in the etch mask is removed, thereby reducing the width of the resistor body 1304. After the etch mask is removed, the resultant resistor is illustrated in FIG. 16. As illustrated in FIGS. 15-16 the width of the resistor body 1304 has been reduced from 1502 to 1602. The reduction in width of the resistor body 1304 results a resistor which has a greater resistance value (i.e., decreasing the width decreases the cross sectional area, A, wherein R=ρ·L/A).

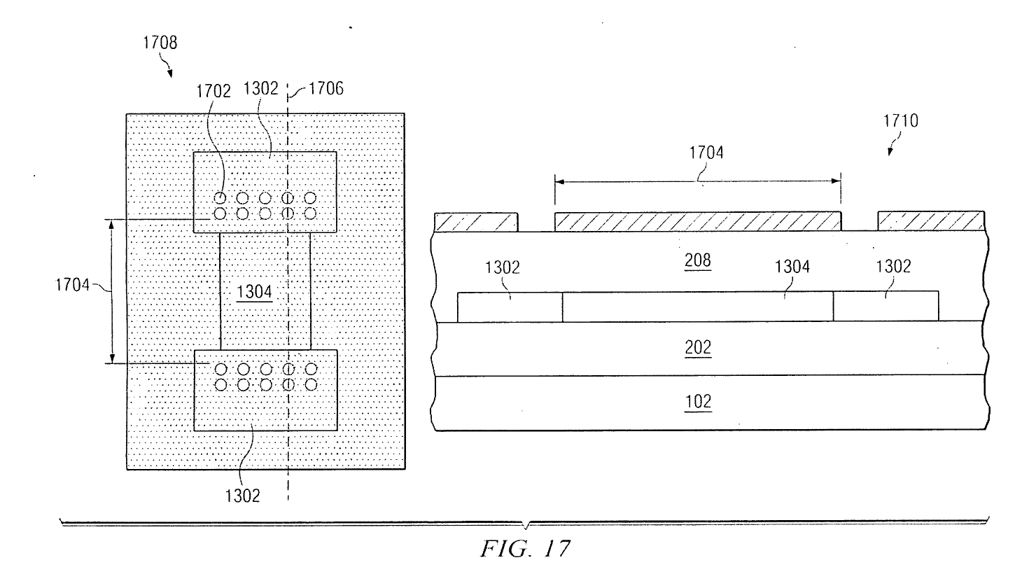

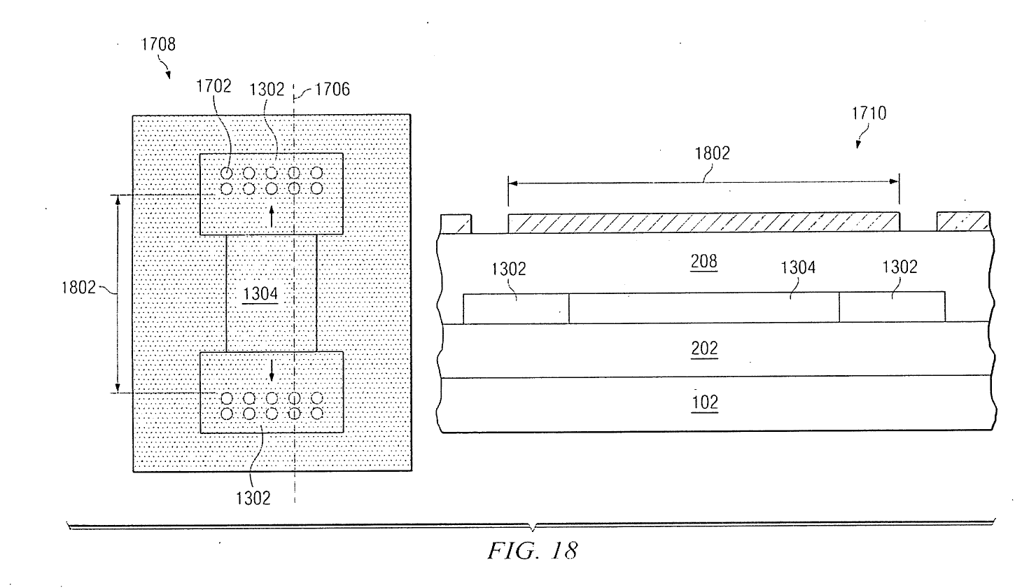

In yet another alternative embodiment, illustrated in FIGS. 17-18, the location of vias contacting the resistor head are adjusted. FIGS. 17-18 illustrate top and side views of a semiconductor resistor, wherein 1706 shows the cross section taken of 1708 illustrated in 1710. More particularly, in FIGS. 17-18, the location of the vias holes 1702 (i.e., used to form contacting the resistor heads 1302) are moved to increase the length of the resistor. For example, FIG. 17 illustrates the initial design of a resistor (i.e., comprising resistor heads 1302 and body 1304) and via holes 1702, wherein the via holes 1702 are configured towards the inside of the resistor heads 1302 (i.e., closer to the resistor body 1304). This configuration corresponds to a resistor length of 1702. If the adjustment map shows that the resistance of the resistor is found to be too small, the location of the via holes 1702 can be adjusted towards the outside of the resistor heads 1302 (i.e., further from the resistor body) as shown in FIG. 18. Movement of the via holes 1702 trims the length of the resistor from 1704 to 1802, where 1802 is greater than 1704. The increase in the length of the resistor results in longer resistor which has a greater resistance value (i.e., increasing the length of the resistor body, L, wherein R=ρ·L/A). Therefore, this movement of the vias holes 1702 increases the resistor length and accordingly increases the resistance of the resistor. It will be appreciated that the method shown in FIGS. 17-18 can easily operate if a silicide mask is not present over the resistor heads.

Therefore, the method of FIG. 10 provides a method of in-situ wafer processing adjustment by which the sheet resistance of resistors comprised within an array are brought in line with the designed values. Accordingly, the method of FIG. 10 provides for a method of reducing variation of resistor performance due to process variation.

While reference is made throughout this document to exemplary structures in discussing aspects of methodologies described herein (e.g., those structures presented in FIGS. 11-18 while discussing the methodology set forth in FIG. 10), those methodologies are not to be limited by the corresponding structures presented. Rather, the methodologies (and structures) are to be considered independent of one another and able to stand alone and be practiced without regard to any of the particular aspects depicted in the Figs. Additionally, layers described herein, can be formed in any suitable manner, such as with spin on, sputtering, growth and/or deposition techniques, etc.

Furthermore, although the structure and methods of this disclosure have been described in reference to the formation of passive devices it will be appreciated that these examples are not intended to limit the scope of the invention. Rather the disclosed structures and methods can be used in the formation of other devices (e.g., non-passive devices) or for alternative purposes associated with general wafer level processing for precisions components.

Also, equivalent alterations and/or modifications may occur to those skilled in the art based upon a reading and/or understanding of the specification and annexed drawings. The disclosure herein includes all such modifications and alterations and is generally not intended to be limited thereby. In addition, while a particular feature or aspect may have been disclosed with respect to only one of several implementations, such feature or aspect may be combined with one or more other features and/or aspects of other implementations as may be desired. Furthermore, to the extent that the terms “includes”, “having”, “has”, “with”, and/or variants thereof are used herein, such terms are intended to be inclusive in meaning—like “comprising.” Also, “exemplary” is merely meant to mean an example, rather than the best. It is also to be appreciated that features, layers and/or elements depicted herein are illustrated with particular dimensions and/or orientations relative to one another for purposes of simplicity and ease of understanding, and that the actual dimensions and/or orientations may differ substantially from that illustrated herein. Further, some regions that are illustrated as having distinct or abrupt edges may not be so precisely delineated, but may instead blend slightly with other regions. This is particularly true of doped or implanted regions that may diffuse with other regions, particularly at abutting edges.

What is claimed is:

1. A method for improving process control of passive devices formed on a semiconductor body, comprising:
forming an adjustable device layer comprised within one or more passive devices on the semiconductor body;
measuring an operational parameter of respective passive devices;
forming an adjustment map illustrating variations in the operational parameter of respective passive devices as a function of a spatial location on the semiconductor body; and
selectively patterning an etch mask layer based upon the adjustment map using a reticleless exposure system; and
selectively trimming the adjustable device layer of the one or more passive devices in-situ to processing the semiconductor body, wherein selectively trimming the adjustable device layer comprises etching the selectively patterned etch mask layer to trim the underlying adjustable device layer in regions exposed by the etch mask layer.

2. The method of claim 1, wherein the etch mask layer comprises a layer of positive photoresist which forms a hard mask over the underlying adjustable device layer.

3. The method of claim 1, wherein the reticleless exposure system comprises a digital micromirror device (DMD) exposure system.

4. The method of claim 1, wherein the adjustment map comprises a detail percentage adjustment to the adjustable device layer within respective contours of the adjustment map.

5. The method of claim 1, wherein the one or more passive devices comprise one or more capacitors respectively comprising:
a lower gate electrode layer;
a dielectric layer configured above the lower gate electrode layer; and
an upper gate electrode layer configured above the dielectric layer, wherein the adjustable device layer comprises the upper gate electrode layer, and wherein selectively trimming the adjustable device layer comprises reducing the size of the upper gate electrode layer.

6. The method of claim 5, wherein the operation parameters comprise a capacitive density.

7. The method of claim 1, wherein the one or more passive devices comprise one or more resistors, respectively comprising:
a resistor body;
a first resistor head coupled to the resistor body;
a second resistor head coupled to the resistor body such that a current flows from the first resistor head, through the resistor body and to the second resistor head.

8. The method of claim 7, wherein adjusting the one or more resistors comprises selectively etching the resistor body to reduce the width of the resistor body, thereby resulting in a higher resistance resistor.

9. The method of claim 7, wherein the first resistor head and the second resistor head are comprised of a silicide layer configured vertically above the resistor body comprised of a lightly doped polysilicon layer.

10. The method of claim 9, wherein adjusting the one or more resistors comprises selectively etching the first or the second resistor head to reduce the size of one or more of the first or the second resistor head, thereby resulting in a higher resistance resistor.

11. The method of claim 7, wherein the resistor body, the first resistor head, and the second resistor head are comprised of a polysilicon.

12. The method of claim 11, wherein adjusting the one or more resistors comprises adjusting a location where via holes are formed on one or more of the first resistor head or the second resistor head.

13. A method for improving process control of one or more capacitors formed on a semiconductor body, comprising:
forming an upper capacitor electrode layer comprised within the one or more capacitors on the semiconductor body;
measuring an operational parameter of respective capacitors;
forming an adjustment map illustrating variations in the operational parameter of respective capacitors as a function of a spatial location on the semiconductor body; and
selectively patterning an etch mask layer based upon the adjustment map using a reticleless exposure system; and
selectively trimming the upper capacitor electrode layer of the one or more capacitors in-situ to processing the semiconductor body, wherein selectively trimming the upper capacitor electrode layer comprises etching the selectively patterned etch mask layer to reduce the size of the underlying upper capacitor electrode layer in regions exposed by the etch mask layer.

14. The method of claim 13, wherein the reticleless exposure system comprises a digital micromirror device (DMD) exposure system.

15. The method of claim 14, wherein the operation parameters comprise a capacitive density.

16. The method of claim 14, wherein the operation parameters comprise a capacitor dielectric thickness.

17. A method for improving process control of one or more resistors formed on a semiconductor body, comprising:
forming the one or more resistors on the semiconductor body, wherein respective resistors comprise:
a first resistor head;
a second resistor head;
a resistor body;
measuring a sheet resistance of respective resistors;
forming an adjustment map illustrating variations in the sheet resistance of respective resistors as a function of a spatial location on the semiconductor body; and
selectively patterning an etch mask layer based upon the adjustment map using a reticleless exposure system; and
selectively trimming the one or more resistors in-situ to processing the semiconductor body, wherein selectively trimming the one or more resistors comprises etching the selectively patterned etch mask layer to trim the underlying resistive layer in regions exposed by the etch mask layer.

18. The method of claim 17, wherein the reticleless exposure system comprises a digital micromirror device (DMD) exposure system.

19. The method of claim 18, wherein selectively trimming the one or more resistors comprises reducing the length of a resistive path comprising one or more of the first resistor head, the second resistor head, or the resistor body.

20. The method of claim 18, wherein selectively trimming the one or more resistors comprises reducing the width of the resistor body and thereby increasing.
